(19) United States
(12) Patent Application Publication
(10) Pub. No.: US 2026/0023905 A1
(43) Pub. Date: Jan. 22, 2026

(54) METHOD OF FORMING DIGITAL TWIN ELECTRODE STRUCTURE REFLECTING ELECTRODE MANUFACTURING PROCESS

(71) Applicants: Hyundai Motor Company, Seoul (KR); Kia Corporation, Seoul (KR); Daegu Gyeongbuk Institute of Science and Technology, Daegu (KR)

(72) Inventors: Dae Yeon Hwang, Hwaseong (KR); Kwang Jin Kim, Hwaseong (KR); Hong Seok Min, Hwaseong (KR); Byeong Sun Jun, Hwaseong (KR); Yong Min Lee, Seoul (KR)

(21) Appl. No.: 18/987,837

(22) Filed: Dec. 19, 2024

(30) Foreign Application Priority Data
Jul. 18, 2024 (KR) 10-2024-0094751

(51) Int. Cl. G06F 30/32

(52) U.S. Cl. CPC G06F 30/32

(57) ABSTRACT

A method of forming a digital twin electrode structure reflecting an electrode manufacturing process, including modeling a digital twin electrode structure by simulating a process of manufacturing an electrode that is the target of a digital twin and comparing mechanical and/or electrical characteristics thereof with those of the target electrode, thereby increasing consistency of the digital twin electrode structure. The method involves collecting parameters of the target electrode structure, simulating material behavior using a discrete element method, and refining the model using a finite volume method to incorporate particle contact interface characteristics. The system for forming and verifying the digital twin electrode structure includes a verification module that compares the characteristics of the digital twin electrode with the target electrode, and a feedback mechanism to adjust the model based on deviations identified during the verification process, ensuring a close match between the digital twin and the target electrode structure.

### CROSS-REFERENCE TO RELATED APPLICATION

This application claims, under 35 U.S.C. § 119 (a), the benefit of Korean Patent Application No. 10-2024-0094751, filed on Jul. 18, 2024, the entire contents of which are incorporated herein by reference.

### TECHNICAL FIELD

The present disclosure relates to a method of forming a digital twin electrode structure reflecting an electrode manufacturing process. More particularly, it pertains to a method of forming a digital twin electrode structure reflecting an electrode manufacturing process, in which a digital twin electrode structure may be modeled by simulating a process of manufacturing an electrode that is the target of a digital twin and mechanical and/or electrical characteristics thereof may be compared with those of the target electrode, thereby enhancing the consistency of the digital twin electrode structure.

### BACKGROUND

Lithium secondary batteries are widely used for small devices to large energy storage systems. Recently, the secondary battery market is poised for strong growth due to explosive growth of the electric vehicle market. However, traditional lithium secondary batteries used in electric vehicles carry risks of fire and explosion due to the flammability of liquid electrolytes that contain organic solvents. In response, extensive research is being conducted into all-solid-state batteries, which replace liquid electrolytes with solid electrolytes to improve safety.

A lithium secondary battery is generally configured to include a cathode, an anode, a separator, and an electrolyte solution, and an all-solid-state battery is configured to include a cathode, an anode, and a solid electrolyte layer. Here, the electrodes including the cathode, and the anode are components that directly or indirectly affect the performance of the secondary battery. As a result, extensive efforts are made to analyze electrochemical behavior of the battery and improve performance thereof through various experiments on key factors such as active materials, binders, electrolytes, and conductive materials found in the electrodes.

Since the electrochemical behavior and performance of secondary batteries are determined by various variables, it is expensive and time-consuming to manufacture examples and comparative examples into real objects under the condition that the variables are individually changed and to perform experiments using the same. To address this issue, key performance factors may be quantified and visually analyzed by forming a digital twin of the electrode.

Here, “digital twin” refers to technology that creates an object (twin) identical to the real object in virtual space and verifies the same through various simulations. This digital twin work is performed by 3D formation or 3D reconstruction. Here, 3D formation is a quick and simple method of forming a three-dimensional model in consideration of the types of basic materials input by the user, the inclusion ratio, particle size, etc., but has a problem of low similarity (consistency) with the real object. 3D reconstruction is a method of forming a three-dimensional model by thinly cutting a sample to form multiple specimens and taking the side image (tomogram) of each specimen followed by interpolation, which makes it possible to form a three-dimensional model with high similarity with the actual sample. However, this method is problematic because a lot of time is required to manufacture a specimen, photograph the same, and create an image and also because the sample is deformed by force applied during formation of the specimen by cutting the sample, so the cross-section of the specimen and the cross-section of the sample do not match each other.

### SUMMARY OF THE DISCLOSURE

The present disclosure has been made keeping in mind the problems encountered in the related art, and an object of the present disclosure is to provide a method of forming a digital twin electrode structure to quantify key factors that may directly or indirectly affect battery performance, analyze defect characteristics in the battery, and analyze electrochemical behavior thereof.

In particular, the present disclosure is intended to simulate a method of manufacturing a target electrode in a process of forming a digital twin electrode structure, improving consistency therebetween.

The objects of the present disclosure are not limited to the foregoing. The objects of the present disclosure will be able to be clearly understood through the following description and to be realized by the means described in the claims and combinations thereof.

An embodiment of the present disclosure provides a method of forming a digital twin electrode structure, including collecting information on a target electrode structure, modeling a virtual electrode structure by inputting the collected information on the target electrode structure to a first program designed to simulate a process of manufacturing the target electrode structure, and modeling a twin electrode structure reflecting contact interface information of particles in the virtual electrode structure by inputting information on the modeled virtual electrode structure to a second program.

In a further aspect, a method of forming a digital twin electrode structure is provided, the method comprising: a) collecting information on a target electrode structure; b) modeling a virtual electrode structure by inputting the collected information on the target electrode structure to a first program designed to simulate a process of manufacturing the target electrode structure; and c) modeling a twin electrode structure by inputting information from the virtual electrode structure into a second program to simulate particle interaction at contact interfaces.

In the methods, the modeling may be performed by a processor.

In an embodiment, the information on the target electrode structure may include information about materials constituting the target electrode structure.

Also, the information on the target electrode structure may include design information for manufacturing the target electrode structure.

In an embodiment, the first program may include a program capable of analyzing and simulating movement of particles using a discrete element method.

In an embodiment, modeling the virtual electrode structure may include a mixing step of mixing materials constituting the virtual electrode structure.

Also, modeling the virtual electrode structure may include a pressing step of applying a predetermined pressure to materials constituting the virtual electrode structure.

In an embodiment, the second program may include a program capable of analyzing and simulating contact interface information of particles using a finite volume method.

In an embodiment, modeling the twin electrode structure may include modifying modeling of the twin electrode structure by comparing CT (computed tomography) images of the twin electrode structure and the target electrode structure. In an embodiment, the method may further include a verification step of comparing characteristics of the modeled twin electrode structure and the target electrode structure.

As such, the verification step may be performed in a manner in which, if consistency between characteristics of the target electrode structure and characteristics of the twin electrode structure is greater than or equal to a preset value, modeling of the twin electrode structure is ended, whereas if the consistency is less than the preset value, correction is performed such that the characteristics of the twin electrode structure become equal to the characteristics of the target electrode structure and then the verification step is performed again.

In an embodiment, the preset consistency may be 85% to 100%.

In an embodiment, the correction may include changing at least one selected from among connectivity between materials in the twin electrode structure, distribution ratio, surface modification of a material, and characteristics of byproducts.

In an embodiment, the verification step may include verifying mechanical characteristics of the twin electrode structure.

As such, the mechanical characteristics may include plastic characteristics and elastic characteristics.

In an embodiment, the verification step may include verifying electrical characteristics of the twin electrode structure.

As such, the electrical characteristics may include at least one of effective ionic conductivity (σᵢₒₙ) or effective electronic conductivity (σₑ).

In a further aspect, a method of forming a digital twin electrode structure that simulates the manufacturing and performance characteristics of an electrode is provided, the method comprising: a) collecting parameters specific to a target electrode structure; b) generating a 3D virtual model of the target electrode structure by incorporating the parameters; c) simulating the manufacturing process of the target electrode structure, using a discrete element method to replicate material behavior during the formation of the virtual electrode structure; d) refining the virtual model by incorporating contact interface characteristics of particles using a finite volume method; and e) forming a digital twin electrode structure that reflects properties of the target electrode structure.

In aspects of the method, the step of simulating the manufacturing process of the target electrode structure may comprise: a) adjusting a mixing step of mixing materials constituting the virtual electrode structure, based on the material characteristics of the target electrode structure; and b) optimizing a pressing step of applying a predetermined pressure to materials constituting the virtual electrode structure, by applying pressure variations to different regions of the virtual electrode structure to account for differences in material distribution and structural properties.

In further aspects, a system for forming and verifying a digital twin electrode structure is provided, the system comprising: a) a first program configured to model a virtual electrode structure by simulating the manufacturing process of a target electrode structure using the discrete element method; b) a second program configured to model a twin electrode structure by simulating particle contact interfaces using the finite volume method; and c) a verification module configured to compare characteristics of the twin electrode structure with those of the target electrode structure. In aspects, the system suitably comprises feedback mechanism that adjusts the virtual electrode model based on deviations identified during verification.

As discussed, the method and system suitably include use of a controller or processer.

### BRIEF DESCRIPTION OF THE DRAWINGS

The above and other features of the present disclosure will now be described in detail referring to certain example embodiments thereof illustrated in the accompanying drawings, which are given hereinbelow by way of illustration only, and thus are not limitative of the present disclosure, and wherein:

FIG. 1 is a flowchart showing a process of forming a digital twin electrode structure according to an embodiment of the present disclosure;

FIG. 2 shows a mixing step according to the present disclosure;

FIG. 3 shows application of linear pressure in a pressing step according to the present disclosure;

FIG. 4 shows application of surface pressure in the pressing step according to the present disclosure;

FIG. 5 shows modeling a twin electrode structure according to the present disclosure;

FIGS. 6 and 7 show a process of calculating the Wₚₗ/Wₜₒₜ value through a micro-indentation test on a target electrode structure;

FIG. 8 shows a process of calculating the Wₚₗ/Wₜₒₜ value by performing micro-indentation simulation for the twin electrode structure using a first program;

FIG. 9 shows a process of obtaining effective ionic conductivity (Cion) of the twin electrode structure using a second program;

FIG. 10 shows a process of comparing the effective ionic conductivity of the twin electrode structure and the effective ionic conductivity of the target electrode structure;

FIG. 11 shows a process of obtaining effective electronic conductivity (ge) of the twin electrode structure using the second program; and

FIG. 12 shows a process of comparing the effective electronic conductivity of the twin electrode structure and the effective electronic conductivity of the target electrode structure.

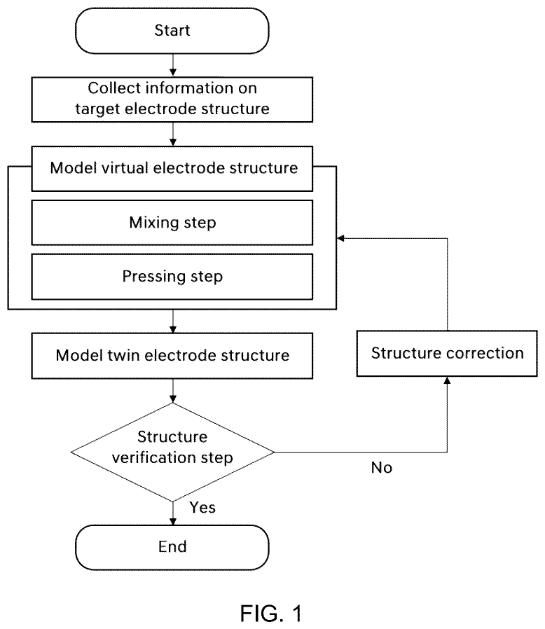

### DETAILED DESCRIPTION

The above and other objects, features and advantages of the present disclosure will be more clearly understood from the following preferred embodiments taken in conjunction with the accompanying drawings. However, the present disclosure is not limited to the embodiments disclosed herein and may be modified into different forms. These embodiments are provided to thoroughly explain the disclosure and to sufficiently transfer the spirit of the present disclosure to those skilled in the art.

Throughout the drawings, the same reference numerals will refer to the same or like elements. For the sake of clarity of the present disclosure, the dimensions of structures are depicted as being larger than the actual sizes thereof. It will be understood that, although terms such as “first”, “second”, etc. may be used herein to describe various elements, these elements are not to be limited by these terms. These terms are only used to distinguish one element from another element. For instance, a “first” element discussed below could be termed a “second” element without departing from the scope of the present disclosure. Similarly, the “second” element could also be termed a “first” element. As used herein, the singular forms are intended to include the plural forms as well, unless the context clearly indicates otherwise.

It will be further understood that the terms “comprise”, “include”, “have”, etc., when used in this specification, specify the presence of stated features, integers, steps, operations, elements, components, or combinations thereof, but do not preclude the presence or addition of one or more other features, integers, steps, operations, elements, components, or combinations thereof. Also, it will be understood that when an element such as a layer, film, area, or sheet is referred to as being “on” another element, it may be directly on the other element, or intervening elements may be present therebetween. Similarly, when an element such as a layer, film, area, or sheet is referred to as being “under” another element, it may be directly under the other element, or intervening elements may be present therebetween.

Unless otherwise specified, all numbers, values, and/or representations that express the amounts of components, reaction conditions, polymer compositions, and mixtures used herein are to be taken as approximations including various uncertainties affecting measurement that inherently occur in obtaining these values, among others, and thus should be understood to be modified by the term “about” in all cases. Furthermore, when a numerical range is disclosed in this specification, the range is continuous, and includes all values from the minimum value of said range to the maximum value thereof, unless otherwise indicated. Moreover, when such a range pertains to integer values, all integers including the minimum value to the maximum value are included, unless otherwise indicated.

In the present specification, when a range is described for a variable, it will be understood that the variable includes all values including the end points described within the stated range. For example, the range of “5 to 10” will be understood to include any subranges, such as 6 to 10, 7 to 10, 6 to 9, 7 to 9, and the like, as well as individual values of 5, 6, 7, 8, 9 and 10, and will also be understood to include any value between valid integers within the stated range, such as 5.5, 6.5, 7.5, 5.5 to 8.5, 6.5 to 9, and the like. Also, for example, the range of “10% to 30%” will be understood to include subranges, such as 10% to 15%, 12% to 18%, 20% to 30%, etc., as well as all integers including values of 10%, 11%, 12%, 13% and the like up to 30%, and will also be understood to include any value between valid integers within the stated range, such as 10.5%, 15.5%, 25.5%, and the like.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. These terms are merely intended to distinguish one component from another component, and the terms do not limit the nature, sequence or order of the constituent components. As used herein, the term “and/or” includes any and all combinations of one or more of the associated listed items. In addition, the terms “unit”, “-er”, “-or”, and “module” described in the specification mean units for processing at least one function and operation and can be implemented by hardware components or software components and combinations thereof.

Although example embodiment is described as using a plurality of units to perform the example process, it is understood that the example processes may also be performed by one or plurality of modules. Additionally, it is understood that the term controller/control unit refers to a hardware device that includes a memory and a processor and is specifically programmed to execute the processes described herein. The memory is configured to store the modules, and the processor is specifically configured to execute said modules to perform one or more processes which are described further below.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

An embodiment of the present disclosure relates to a method of forming a digital twin electrode structure, including collecting information on a target electrode structure, modeling a virtual electrode structure by inputting the collected information on the target electrode structure to a first program designed to simulate a process of manufacturing the target electrode structure, and modeling a twin electrode structure reflecting contact interface information of particles in the virtual electrode structure by inputting information on the modeled virtual electrode structure to a second program. Below is a detailed description of individual steps.

### Collecting Information on Target Electrode Structure

First, information on the target electrode structure may be collected. The “target electrode structure” may refer to a portion of an electrode that is a target for analyzing electrochemical behavior and simulating performance thereof through digital twinning.

Here, the target electrode may include an anode or a cathode. The anode or the cathode may contain materials commonly used in the art as components.

In general, the target electrode may include an active material capable of reversibly storing and releasing lithium, an electrolyte for improving lithium-ion conductivity of the electrode, a binder for physically bonding components in the electrode, a conductive material for improving electronic conductivity of the electrode, etc.

For example, when the target electrode is an anode, it may include an anode active material, and when the electrode is a cathode, it may include a cathode active material. Also, when the target electrode is used in a lithium-ion battery, it may include an electrolyte solution with which the active material is impregnated, and when the target electrode is a composite electrode used in an all-solid-state battery, it may include a solid electrolyte. As necessary, the above components may be selectively included.

In one embodiment, information on the target electrode structure may include information about materials constituting the target electrode structure. For example, such information may include information about the active material, binder, conductive material, or electrolyte that constitutes the target electrode structure. Here, information about the materials may include the types of active material, binder, electrolyte, conductive material, etc., particle size, particle size distribution, Young's modulus, ionic conductivity, electronic conductivity, particle shape, and the like.

Also, information on the target electrode structure may include design information for manufacturing the target electrode structure. In general, in order to manufacture an electrode, there may be a need not only for information about the components constituting the electrode, but also for information about the ratio therebetween, the rotation speed, time, and temperature when performing the mixing process, and the method of application of pressure and the strength of pressure that is applied when performing the pressing process.

Accordingly, the design information may include at least the ratio between the materials constituting the target electrode structure, information necessary to perform the mixing process, and information necessary to perform the pressing process.

### Modeling Virtual Electrode Structure

In this step, a virtual electrode structure may be modeled by inputting the collected information on the target electrode structure to a first program designed to simulate the process of manufacturing the target electrode structure.

A detailed description of a general method of manufacturing the target electrode is as follows. An electrode slurry is prepared by adding the materials constituting the target electrode to a solvent followed by mixing. Thereafter, an electrode layer is formed by applying the electrode slurry onto a substrate or an electrode current collector followed by pressing and drying. Briefly, the general process of manufacturing the target electrode involves a mixing step and/or a pressing step.

Accordingly, the “process of manufacturing the target electrode structure” to be simulated according to the present disclosure may include a mixing step and/or a pressing step.

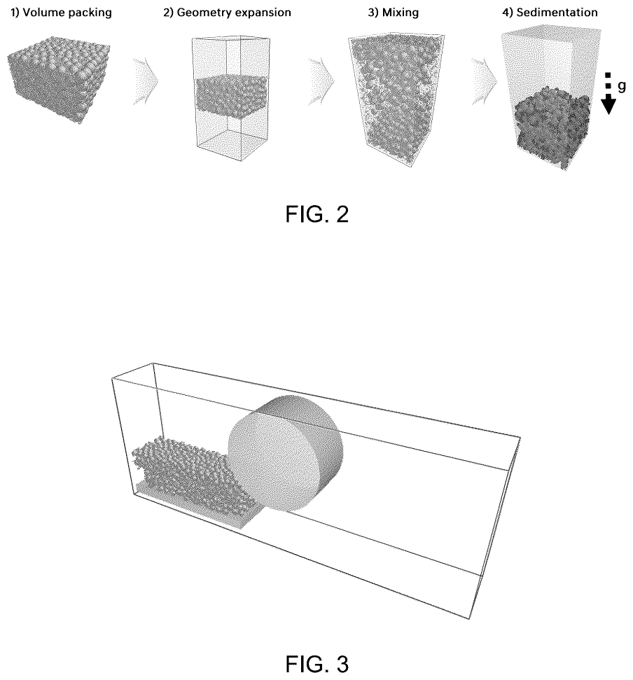

In one embodiment, modeling the virtual electrode structure according to the present disclosure may include a mixing step of mixing materials constituting the virtual electrode structure, which is described in more detail with reference to FIG. 2. Specifically, information on the target electrode structure is input to the first program and a 3D model is created based thereon. The 3D model may be provided in the form in which particles corresponding to materials constituting the virtual electrode structure are packed in a predetermined volume (volume packing). In addition, the quantity of particles corresponding to the materials constituting the 3D model, such as the active material, binder, electrolyte, conductive material, etc., may correspond to vol % of the active material, binder, electrolyte, conductive material, etc. in the target electrode identified in the step of collecting information on the target electrode structure. Here, vol % may mean the volume without considering interaction between particles.

Next, the virtual space where the 3D model is located is expanded to a predetermined volume (geometry expansion) followed by mixing. As such, the mixing conditions are preferably those described in the information on the target electrode structure but are not limited thereto and may be set such that the particles of the 3D model are appropriately mixed.

Thereafter, the mixing step may be completed by simulating that the particles dispersed in the expanded space by mixing may be subjected to sedimentation by virtual gravity (g). Here, interaction between particles may be taken into consideration in the mixing step.

In one embodiment, modeling the virtual electrode structure may include a pressing step of applying a predetermined pressure to the materials constituting the virtual electrode structure. Preferably, the pressing step is performed after the mixing step.

The pressing step may include a process of modeling a virtual electrode structure by applying linear pressure and/or surface pressure to the 3D model based on information on the target electrode structure or the 3D model subjected to the mixing step. Here, interaction between particles may be taken into consideration in the pressing step.

In general, the linear pressure may be applied using a roll press, as shown in FIG. 3. For example, pressure may be applied to the 3D model by reflecting the size of the roll press and the magnitude of linear pressure applied thereby included in the design information among the information on the target electrode structure.

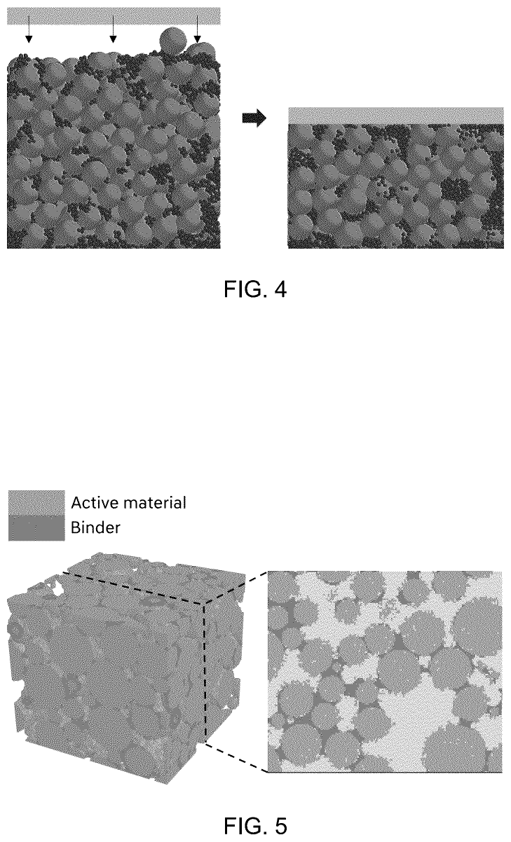

Also, as shown in FIG. 4, surface pressure may be applied to the 3D model using a predetermined pressure plate. For example, pressure may be applied to the 3D model by reflecting the magnitude of surface pressure and pressure application time included in the design information among the information on the target electrode structure.

Meanwhile, in this step, modeling of the virtual electrode structure through creation of the 3D model and simulation thereof may be performed by the first program. In one embodiment, the first program may include a program capable of analyzing and simulating the movement of particles using a discrete element method.

The discrete element method is a stress analysis method that divides a structure into elements of virtually finite size and analyzes the structure as a collection of these elements. The first program may be used without any particular limitation, so long as it is able to model a virtual electrode structure by simulating the process of manufacturing the target electrode structure, for example, the mixing step and the pressing step, using the discrete element method. For example, EDEM from Altair may be used.

As described above, the method of forming the twin electrode structure according to the present disclosure is capable of improving consistency with the target electrode structure by modeling the virtual electrode structure by simulating the process of manufacturing the target electrode structure, such as the mixing step and/or the pressing step. Also, the use of the first program capable of analyzing movement of particles in consideration of interaction between particles makes it possible to obtain more accurate positional information about the materials constituting the virtual electrode structure.

### Modeling Twin Electrode Structure

In this step, a twin electrode structure reflecting contact interface information of the particles in the virtual electrode structure may be modeled by inputting information on the modeled virtual electrode structure to a second program.

The particles for the active material, binder, conductive material, solid electrolyte, etc. in the target electrode structure may be present in the form of primary particles, and secondary particles, which are large particles that may be physically distinguished, may be formed by aggregating the primary particles. In this step, simulation may be performed by reflecting a case in which particles in the virtual electrode structure are formed into secondary particles using the second program. Accordingly, a twin electrode structure that reflects contact interface information of particles in the virtual electrode structure may be modeled.

In one embodiment, the second program may include a program capable of analyzing and simulating contact interface information of particles using a finite volume method. The finite volume method is a numerical solution of partial differential equations that describe the flow of air or liquid or the flow of heat and is a type of difference method suitable for treating equations described in the form of conservation laws.

The second program may be used without any particular limitation, so long as it is able to model a twin electrode structure by analyzing and simulating contact interface information of primary and secondary particles due to formation of secondary particles from the particles in the virtual electrode structure using the finite volume method. For example, GEODICT from Math2Market may be used.

Meanwhile, since the first program serves to depict particles using spheres without particle deformation, it may be difficult to accurately depict contact between particles in the actual target electrode structure.

Since the second program serves to perform simulation or modeling based on voxel technology for rendering objects that may be divided into small cubes or volume elements, interaction and overlap between particles may not be allowed. The second program enables voxelization of the virtual electrode structure modeled by the first program to allow smooth contact of overlapping portions, thereby performing secondary modeling (e.g., modeling of a twin electrode structure) similar to the actual electrode structure. Also, modeling the twin electrode structure may include modifying modeling of the twin electrode structure by comparing CT (computed tomography) images of the twin electrode structure and the target electrode structure. As the first program and the second program, the same or different programs may be used so long as they are able to fully perform respective functions thereof.

As described above, the method of forming the twin electrode structure according to the present disclosure is capable of improving consistency with the target electrode structure by modeling the twin electrode structure by reflecting contact interface information of the particles in the virtual electrode structure.

### Verification Step

In one embodiment, a verification step of comparing characteristics of the modeled twin electrode structure and the target electrode structure may be further included. This serves to reduce errors that may occur in the modeling process because the digital twin electrode structure according to the present disclosure is not based on hundreds of tomograms of the actual target electrode structure.

The verification step may be performed in a manner in which, if the consistency between characteristics of the target electrode structure and characteristics of the twin electrode structure is greater than or equal to a preset value, modeling of the twin electrode structure is ended, whereas if the consistency is less than the preset value, correction is performed such that the characteristics of the twin electrode structure become equal to the characteristics of the target electrode structure and then the verification step is performed again.

The consistency may be calculated as [(characteristic value of twin electrode structure/characteristic value of target electrode structure)×100]. In addition, other calculation formula for comparing the degree of matching between the characteristic value of the target electrode structure and the characteristic value of the twin electrode structure may be appropriately applied. For example, it may be calculated as [1−I{(characteristic value of target electrode structure−characteristic value of twin electrode structure)/characteristic value of target electrode structure}|]*100.

Also, the preset consistency may be 85% to 100%. If the preset consistency is less than 85%, even when consistency of the modeled digital twin electrode structure is greater than or equal to the preset consistency, similarity with the actual target electrode structure may be reduced.

Here, the “characteristic value” may be a numerical value related to the mechanical or electrical characteristics of each electrode structure.

For example, the mechanical characteristics may include plastic and elastic characteristics, and the characteristic value thereof may be determined by dividing the plastic deformation energy (Wₚₗ) measured through a micro-indentation test by the total deformation energy (Wₜₒₜ).

The consistency for verifying the mechanical characteristics of the twin electrode structure may be determined in a manner in which the Wₚₗ/Wₜₒₜ value is calculated by performing micro-indentation simulation for the twin electrode structure using the first program, and the Wₚₗ/Wₜₒₜ value is calculated by performing a micro-indentation test on the actually manufactured target electrode structure, followed by division to correspond to the definition of the consistency described above.

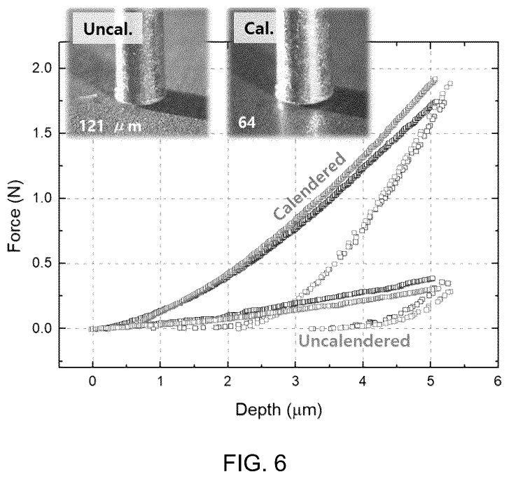

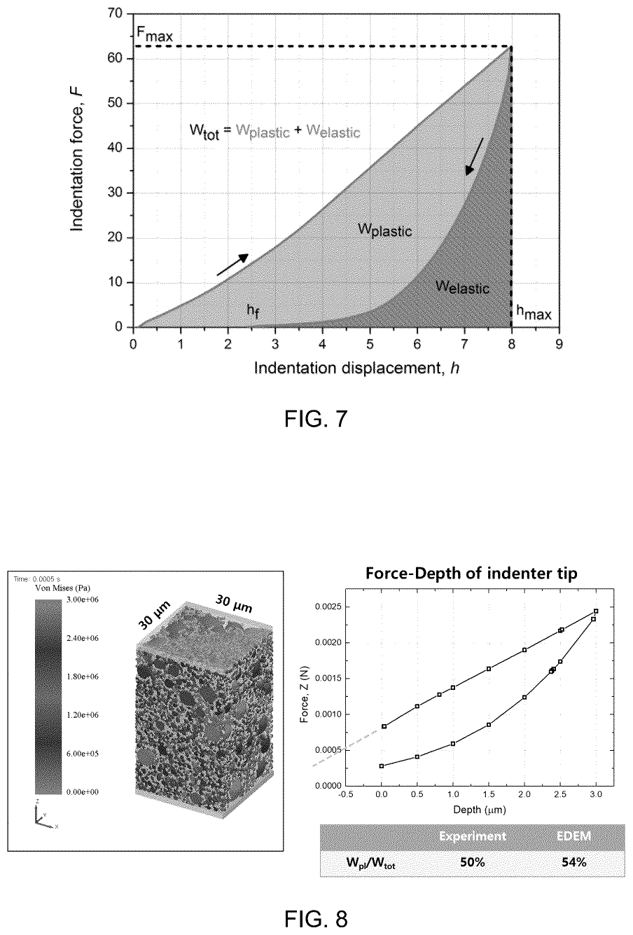

FIGS. 6 and 7 show the process of calculating the Wₚₗ/Wₜₒₜ value by performing a micro-indentation test on the actually manufactured target electrode structure, and FIG. 8 shows the process of calculating the Wₚₗ/Wₜₒₜ value by performing micro-indentation simulation for the twin electrode structure using the first program.

In addition, any characteristic value that well represents the mechanical characteristics of the twin electrode structure may be compared without particular limitation.

Also, the electrical characteristics may include ionic conductivity and electrical conductivity of the electrode structure, and the characteristic value thereof may be represented as effective ionic conductivity (σᵢₒₙ) and/or effective electronic conductivity (σₑ).

The consistency for verifying the electrical characteristics of the twin electrode structure may be determined in a manner in which the effective ionic conductivity (Cion) or the effective electronic conductivity (σₑ) of the twin electrode structure is calculated using the second program, and the effective ionic conductivity (σᵢₒₙ) or the effective electronic conductivity (σₑ) is calculated by performing impedance measurement on the actually manufactured target electrode structure, followed by division to correspond to the definition of the consistency described above.

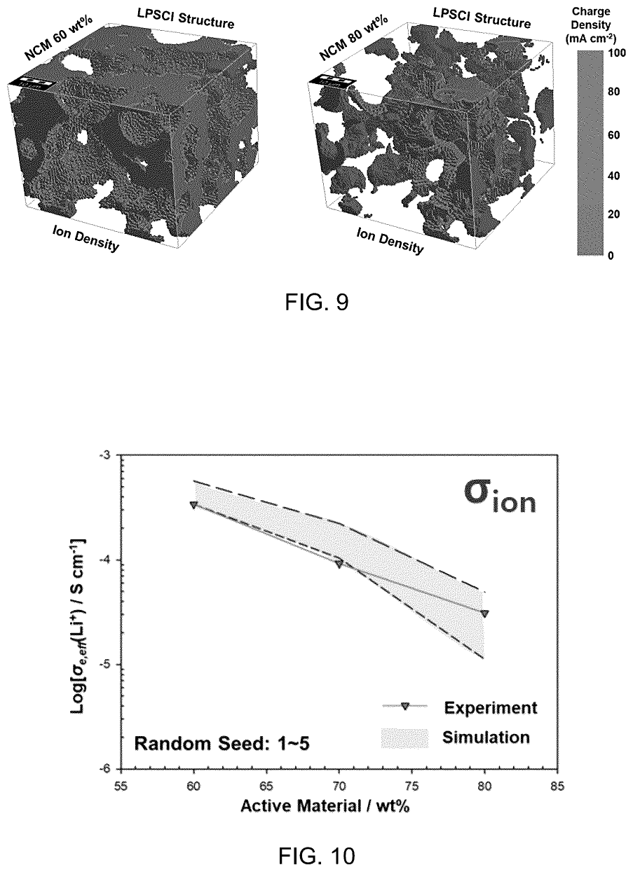

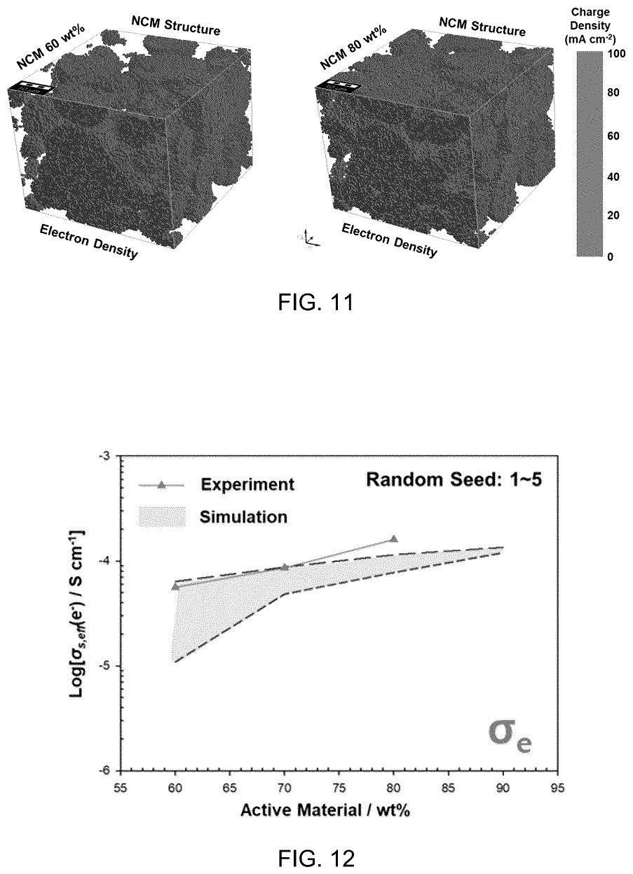

FIG. 9 shows the process of obtaining the effective ionic conductivity (σᵢₒₙ) of the twin electrode structure using the second program, and FIG. 10 shows the process of comparing the effective ionic conductivity of the twin electrode structure and the effective ionic conductivity of the target electrode structure. In addition, FIG. 11 shows the process of obtaining the effective electronic conductivity (σₑ) of the twin electrode structure using the second program, and FIG. 12 shows the process of comparing the effective electronic conductivity of the twin electrode structure and the effective electronic conductivity (σₑ) of the target electrode structure.

In addition, any characteristic value that well represents the electrical characteristics of the twin electrode structure may be compared without particular limitation.

If both the consistency regarding the mechanical characteristics and the consistency regarding the electrical characteristics calculated as above are greater than or equal to the preset value, modeling of the twin electrode structure may be ended.

On the other hand, if either the consistency regarding the mechanical characteristics or the consistency regarding the electrical characteristics is less than the preset value, correction may be performed such that the characteristics of the twin electrode structure become equal to the characteristics of the target electrode structure.

As such, the correction may include a change that increases or decreases the mechanical or electrical characteristics of the twin electrode structure. In one embodiment, the correction may include changing at least one selected from among connectivity between materials in the twin electrode structure, distribution ratio, surface modification of a material, and characteristics of byproducts.

For example, in relation to the electrical characteristics of the twin electrode structure, if the effective ionic conductivity of the twin electrode structure is lower than the effective ionic conductivity of the target electrode structure, the distribution rate of the binder located in the solid electrolyte may be decreased or the surface of the solid electrolyte may be coated with a material having higher ionic conductivity. In contrast, if the effective ionic conductivity of the twin electrode structure is higher than the effective ionic conductivity of the target electrode structure, connectivity of the solid electrolyte may be decreased, the distribution rate of the binder located in the solid electrolyte may be increased, or the surface of the solid electrolyte may be coated with a material having lower ionic conductivity.

In addition, if the effective electronic conductivity of the twin electrode structure is lower than the effective electronic conductivity of the target electrode structure, the active material in the twin electrode may be coated with a material having higher electrical conductivity, whereas if the effective electronic conductivity of the twin electrode structure is higher than the effective electronic conductivity of the target electrode structure, the active material in the twin electrode may be coated with a material having lower electrical conductivity.

In relation to the mechanical characteristics of the twin electrode structure, if the Wₚₗ/Wₜₒₜ value of the twin electrode structure is lower or higher than the Wₚₗ/Wₜₒₜ value of the target electrode structure, the mechanical characteristics (elastic modulus, yield stress, etc.) of each component of the twin electrode structure, for example, active material, binder, electrolyte, or conductive material may be corrected to become equal to those of the target electrode structure.

After performing correction such that the characteristics of the twin electrode structure become equal to the characteristics of the target electrode structure, the verification step of comparing the characteristics of the twin electrode structure with the characteristics of the target electrode structure may be performed again. If the consistency between the twin electrode structure and the target electrode structure after correction is less than the preset value, the correction process may be repeated until the consistency is greater than or equal to the preset value.

As such, depending on the contents of the correction, the verification step may be performed immediately after correction, the verification step may be performed after remodeling the virtual electrode structure and the twin electrode structure by reflecting the correction contents, or the verification step may be performed by remodeling only the twin electrode structure.

When the verification step is performed by comparing the mechanical and electrical characteristics of the modeled twin electrode structure with the mechanical and electrical characteristics of the target electrode structure in this way, not only may the structure be modeled quickly, but also the similarity with the real object may be increased.

In particular, in the verification step, the connectivity between electrode materials, location, and other material characteristics may be additionally corrected to increase the consistency of mechanical and electrical characteristics, thereby further increasing similarity between the actual target electrode structure and the twin electrode structure manufactured through the digital twin process.

As is apparent from the foregoing, a method of forming a digital twin electrode structure according to the present disclosure is capable of modeling a virtual electrode structure by inputting information on a target electrode structure to a first program designed to simulate a process of manufacturing the target electrode structure, and modeling a twin electrode structure that reflects contact interface information of particles in the virtual electrode structure by inputting information on the modeled virtual electrode structure to a second program, thereby increasing consistency between the target electrode structure and the twin electrode structure.

In addition, mechanical and electrical characteristics of the modeled twin electrode structure are verified by comparison with mechanical and electrical characteristics of the target electrode structure, whereby the structure can be modeled quickly and similarity with a real object can be increased.

In particular, in the verification step, the connectivity between electrode materials, location, and other material characteristics can be additionally corrected to increase the consistency of mechanical and electrical characteristics, thereby further increasing the similarity between the actual and modeled structures.

The effects of the present disclosure are not limited to the foregoing. It should be understood that the effects of the present disclosure include all effects that can be inferred from the description of the present disclosure.

As the embodiments of the present disclosure have been described above, those skilled in the art will appreciate that various modifications and alterations are possible through change, deletion or addition of components without departing from the scope and spirit of the present disclosure as described in the accompanying claims, which will also be said to be included within the scope of rights of the present disclosure.

What is claimed is:

1. A method of forming a digital twin electrode structure, comprising:
collecting information on a target electrode structure;
modeling a virtual electrode structure by inputting the collected information on the target electrode structure to a first program designed to simulate a process of manufacturing the target electrode structure; and
modeling a twin electrode structure by inputting information from the virtual electrode structure into a second program to simulate particle interaction at contact interfaces.

2. The method of claim 1, wherein the information on the target electrode structure comprises information about materials constituting the target electrode structure.

3. The method of claim 1, wherein the information on the target electrode structure comprises design information for manufacturing the target electrode structure.

4. The method of claim 1, wherein the first program comprises a program capable of analyzing and simulating movement of particles using a discrete element method.

5. The method of claim 1, wherein modeling the virtual electrode structure comprises a mixing step of mixing materials constituting the virtual electrode structure.

6. The method of claim 1, wherein modeling the virtual electrode structure comprises a pressing step of applying a predetermined pressure to materials constituting the virtual electrode structure.

7. The method of claim 1, wherein the second program comprises a program capable of analyzing and simulating contact interface information of particles using a finite volume method.

8. The method of claim 1, wherein modeling the twin electrode structure comprises modifying modeling of the twin electrode structure by comparing computed tomography (CT) images of the twin electrode structure and the target electrode structure.

9. The method of claim 1, further comprising a verification step of comparing characteristics of the modeled twin electrode structure and the target electrode structure.

10. The method of claim 9, wherein the verification step involves comparing the characteristics of the target electrode structure with the characteristics of the twin electrode structure, and:
if the consistency between the two structures is greater than or equal to a preset threshold, the modeling process is concluded;
if the consistency is below the preset threshold, corrections are made to the twin electrode structure to match the characteristics of the target electrode structure, and the verification step is repeated.

11. The method of claim 10, wherein the preset consistency is about 85% to 100%.

12. The method of claim 10, wherein the correction comprises changing at least one selected from among connectivity between materials in the twin electrode structure, distribution ratio, surface modification of a material, and characteristics of byproducts.

13. The method of claim 10, wherein the verification step comprises verifying mechanical characteristics of the twin electrode structure.

14. The method of claim 13, wherein the mechanical characteristics comprise plastic characteristics and elastic characteristics.

15. The method of claim 10, wherein the verification step comprises verifying electrical characteristics of the twin electrode structure.

16. The method of claim 15, wherein the electrical characteristics comprise at least one of effective ionic conductivity (σᵢₒₙ) or effective electronic conductivity (σₑ).

17. A method of forming a digital twin electrode structure that simulates the manufacturing and performance characteristics of an electrode, the method comprising:
collecting parameters specific to a target electrode structure;
generating a 3D virtual model of the target electrode structure by incorporating the parameters;
simulating the manufacturing process of the target electrode structure, using a discrete element method to replicate material behavior during the formation of the virtual electrode structure;
refining the virtual model by incorporating contact interface characteristics of particles using a finite volume method; and
forming a digital twin electrode structure that reflects properties of the target electrode structure.

18. The method of claim 17, wherein the step of simulating the manufacturing process of the target electrode structure comprises:
adjusting a mixing step of mixing materials constituting the virtual electrode structure, based on the material characteristics of the target electrode structure; and
optimizing a pressing step of applying a predetermined pressure to materials constituting the virtual electrode structure, by applying pressure variations to different regions of the virtual electrode structure to account for differences in material distribution and structural properties.

19. A system for forming and verifying a digital twin electrode structure, the system comprising:
a first program configured to model a virtual electrode structure by simulating the manufacturing process of a target electrode structure using the discrete element method;
a second program configured to model a twin electrode structure by simulating particle contact interfaces using the finite volume method; and
a verification module configured to compare characteristics of the twin electrode structure with those of the target electrode structure.

20. The system of claim 19, further comprising a feedback mechanism that adjusts the virtual electrode model based on deviations identified during verification.
